(19) United States
(12) Patent Application Publication
(10) Pub. No.: US 2015/0372198 A1
(43) Pub. Date: Dec. 24, 2015

(54) LIGHT EMITTING MODULE

(71) Applicant: KOITO MANUFACTURING CO., LTD., Tokyo (JP)

(72) Inventors: Hisayoshi DAICHO, Shizuoka-shi (JP); Shogo SUGIMORI, Shizuoka-shi (JP)

(73) Assignee: KOITO MANUFACTURING CO., LTD., Tokyo (JP)

(21) Appl. No.: 14/746,164

(22) Filed: Jun. 22, 2015

(30) Foreign Application Priority Data
Jun. 24, 2014 (JP) 2014-129541

(51) Int. Cl. H01L 33/50; H01S 5/50

(52) U.S. Cl. CPC H01L 33/50; H01S 5/50

(57) ABSTRACT

A light emitting module includes a semiconductor light emitting element, an optical wavelength conversion member configured to convert the wavelength of element light emitted from the semiconductor light emitting element and to emit converted light, having a color different from the element light, a transmitting member disposed between the semiconductor light emitting element and the optical wavelength conversion member and configured to allow the element light to be transmitted therethrough, the transmitting member being made of a thermal conductive material that transfers the heat generated from the optical wavelength conversion member to the outside, and a transparent adhesive bonding the optical wavelength conversion member and the transmitting member to each other, the adhesive having a thickness of 2.0 μm or less.

### CROSS-REFERENCE TO RELATED APPLICATION

The present application claims priority from Japanese Patent Application No. 2014-129541 filed on Jun. 24, 2014, the entire content of which is incorporated herein by reference.

### BACKGROUND

1. Technical Field

The present invention relates to a light emitting module.

2. Related Art

There has been suggested a semiconductor light emitting device that uses a semiconductor light emitting element such as a light emitting diode (LED) and a laser diode (LD). Further, a method of realizing a white light source by a combination of a semiconductor light emitting element and a phosphor has been variously devised (see Patent Documents 1 and 2).

Patent Document 1: Japanese Patent Laid-Open Publication No. 2008-305936

Patent Document 2 Japanese Patent Laid-Open Publication No. 2009-289976

By the way, when the light emitted from the semiconductor light emitting element is subjected to the down-conversion by the phosphor, the occurrence of stroke loss due to the energy conversion cannot be avoided. Due to the stroke loss, heat is generated from the phosphor and therefore the temperature of the phosphor rises. Especially, when the brightness is increased in accordance with the improvement in the performance of the semiconductor hot emitting element, the amount of heat generated from the phosphor is further increased. Therefore, a suitable heat dissipation measure is required.

### SUMMARY

Exemplary embodiments of the invention provide a light emitting module with the improved heat dissipation.

A light emitting module according to an exemplary embodiment, comprises:

a semiconductor light emitting element;

an optical wavelength conversion member configured to convert the wavelength of element light emitted from the semiconductor light emitting element and to emit converted light having a color different from the element light;

a transmitting member disposed between the semiconductor light emitting element and the optical wavelength conversion member and configured to allow the element light to be transmitted therethrough, the transmitting member being made of a thermal conductive material that transfers the heat generated from the optical wavelength conversion member to the outside; and

a transparent adhesive bonding the optical wavelength conversion member and the transmitting member to each other, the adhesive having a thickness of 20 μm or less.

The term “element light” means light emitted from the semiconductor light emitting element, and the term “converted light” means light whose wavelength has been converted. According to this aspect, the heat generated from the optical wavelength conversion member when the wavelength of element light emitted from the semiconductor light emitting element is converted can be dissipated to the outside via the transmitting member made of a thermal conductive material.

The transmitting member may have light transmittance of 40% or more and thermal conductivity of 10 W/(m·K) or more.

The semiconductor light emitting element may emit ultraviolet light or short-wavelength visible light. Even in the case of using such semiconductor light emitting element, the deterioration of adhesive can be reduced when the adhesive is made of dimethyl silicone, for example.

The semiconductor light emitting element may be a laser diode, and the transmitting member may be disposed at a place that is spaced apart from a light emitting portion of the semiconductor light emitting element. Since the laser diode and the transmitting member are arranged to be spaced apart, the oscillation of the laser diode is effectively performed.

The transmitting member may be made of a material having thermal conductivity higher than that of the optical wavelength conversion member. In this way, the heat of the optical wavelength conversion member can be effectively transferred to the transmitting member.

According to the present invention, it is possible to improve the heat dissipation of the light emitting module.

### BRIEF DESCRIPTION OF THE DRAWINGS

FIG. 1 is a view showing a schematic configuration of a light emitting module according to a first embodiment.

FIG. 2 is a view showing a schematic configuration of a light emitting module according to a second embodiment.

FIG. 3 is a view showing a schematic configuration of light emitting module according to a third embodiment.

### DETAILED DESCRIPTION

Hereinafter, preferred embodiments of the present invention will be described with reference to the drawings. The same or similar elements, members and process shown in each of the drawings are denoted by the same or similar reference numerals and a duplicated description thereof will be omitted, as appropriate. Further, the embodiment is illustrative and not intended to limit the present invention. It should be noted that all the features and their combinations described in the embodiment are not necessarily considered as an essential part of the present invention.

### First Embodiment

### (Light Emitting Module)

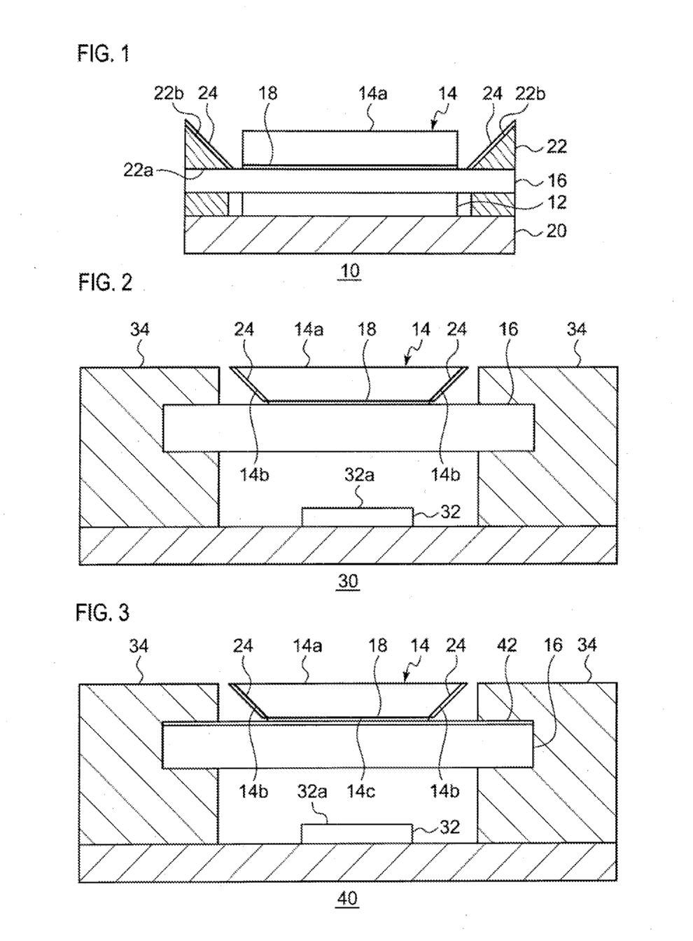

FIG. 1 is a view showing a schematic configuration of a light emitting module 10 according to a first embodiment. The light emitting module 10 includes a semiconductor light emitting element 12, an optical wavelength conversion member 14, a transmitting member 16, and a transparent adhesive 18. The optical wavelength conversion member 14 converts the wavelength of element light emitted from the semiconductor light emitting element 12 and emits converted light having a color different from the element light. The transmitting member 16 is disposed between the semiconductor light emitting element 12 and the optical wavelength conversion member 14 and allows the element light to be transmitted therethrough. The adhesive 18 is provided for bonding the optical wavelength conversion member 14 and the transmitting member 16 to each other. The transmitting member 16 is made of a thermal conductive material that transfers heat generated from the optical wavelength conversion member 14 to the outside.

The semiconductor light emitting element 12 according to the present embodiment is mounted on a mounting substrate 20. Further, a heat sink 22 is provided on an edge of the mounting substrate 20. The heat sink 22 dissipates heat generated from the semiconductor light emitting element 12 or the optical wavelength conversion member 14 to the outside. As the heat sink 22, a high conductive aluminum or copper is preferred.

The heat sink 22 includes a clamping portion 22a for holding an outer edge of the transmitting member 16. An upper region of the heat sink 22 surrounding the optical wavelength conversion member 14 is configured as an inclined surface 22b. A reflective film 24 is provided on the inclined surface 22b. The reflective film 24 reflects the light emitted to the side from the optical wavelength conversion member 14 toward the front (upward in FIG. 1) of the light emitting module 10, so that the brightness of the light emitting module 10 can be improved. As the reflective film 24, a metal film with high reflectivity, such as aluminum or silver, or a white film with high diffusion reflectivity, such as alumina or titania, is preferred.

In this way, in the light emitting module 10 according to the present embodiment, the optical wavelength conversion member 14 is provided on the transmitting member 16 with high thermal conductivity, the element light of the semiconductor light emitting element 12 is incident from an incident surface on the transmitting member side of the optical wavelength conversion member 14, and light is mainly emitted from an emitting surface 14a of the conversion member 14 on the front of the light emitting module. At that time, the element light emitted from the semiconductor light emitting element 12 and the converted light whose wavelength is converted by the optical wavelength conversion member 14 are mixed to each other, so that light having a desired color (e.g., a white color) is created. The light created in this manner is irradiated on the front of the light emitting module 10.

### (Semiconductor Light Emitting Element)

As the semiconductor light emitting element 12, for example, an InGaN-based LED element for emitting ultraviolet ray or short-wavelength visible light (near-ultraviolet light to blue light) is used. Further, it is preferable that the light emitted from the semiconductor light emitting element 12 is ultraviolet ray or short-wavelength visible light, which has a peak wavelength in a. wavelength region of 365 to 470 nm (preferably, 380 to 430 nm). As long as the light emitting element is able to emit ultraviolet ray or short-wavelength visible light, the light emitting element may be an element other than the LED element or may be an LD element or an EL element. Further, in view of the amount of light or the irradiation range, a plurality of semiconductor light emitting elements 12 may be used in the light emitting module 10.

### (Optical Wavelength Conversion Member)

As the optical wavelength conversion member 14, for example, a phosphor layer can be used. The phosphor layer includes (i) a plate-like sintered body formed by sintering a powdered phosphor, (ii) a phosphor film formed by densely packing a powdered phosphor in a transparent binder, and (iii) a single crystal of the phosphor, etc. As the material of the phosphor, the following phosphors can be exemplified. These phosphors emit light by being excited by ultraviolet light (ultraviolet ray) or short-wavelength visible light.

YAG:Ce³⁺ (1)

(Ca₁₋ₓSrₓ)₇(SiO₃)₆Cl₂:Eu²⁺ (2)

(Ca, Sr)₅(PO₄)₃Cl:Eu²⁺ (3)

(Ca, Sr)SiAlN₃:Eu²⁺(4)

β-SiAlON (5)

α-SiAlON (6)

Further, the kind of the phosphor is not limited to one kind. For example, basically, a yellow phosphor and a blue phosphor are combined when the semiconductor light emitting element 12 is a purple LED element. However, a red or green phosphor may be properly combined in consideration of the color rendering properties or the color temperature needed for the irradiation light. Further, in the case where a blue LED element is used as the semiconductor light emitting element 12, only the yellow phosphor may be used or the amount of the blue phosphor may be relatively small, compared with the yellow phosphor.

The optical wavelength conversion member 14 according to the present embodiment has a shape where an area A1 of the emitting surface 14a on the front of the light emitting module 10 becomes wider than an area A2 of the side surface surrounding the emitting surface 14a. In this way, it is possible to reduce the light emitted from the side of the optical wavelength conversion member 14.

### (Transmitting Member)

Preferably, the transmitting member 16 is a transparent substrate with high thermal conductivity. Here, the “transparent substrate” refers to a substrate where absorption in the wavelength region (380 to 780 nm) of visible light is small and, for example, the light transmittance is 40% or more, preferably 60% or more, more preferably 80% or more. Further, the transmitting member 16 may he made of a material with thermal conductivity of 10 W/(m·K) or more, preferably 30 W/(m·K) or more, more preferably 100 W/(m·K) or more. Specifically, a polycrystalline material or a single crystal material such as diamond, SiC, GaN, MgO, sapphire and YAG can be exemplified.

As described above, in the semiconductor light emitting device that uses the wavelength conversion by the optical wavelength conversion member 14 such as the phosphor, heat is generated due to the stroke loss by the down-conversion of the optical wavelength conversion member 14 and therefore the temperature of the optical wavelength conversion member 14 rises. On the other hand, the temperature quenching of the optical wavelength conversion member 14 occurs with the temperature rise. The heat generated from the optical wavelength conversion member 14 when the wavelength of the element light emitted from the semiconductor light emitting element 12 is converted can be dissipated to the outside via the transmitting member 16 made of the thermal conductive material as described above. As a result, it is possible to improve the heat dissipation of the light emitting module 10.

Meanwhile, the transmitting member 16 is made of a material having thermal conductivity higher than that of the optical wavelength conversion member 14. As a result, the heat of the optical wavelength conversion member 14 can be effectively transferred to the transmitting member 16.

### (Adhesive)

The adhesive 18 is used in order to directly bond the optical wavelength conversion member 14 and the transmitting member 16 to each other or in order to indirectly bond the optical wavelength conversion member 14 and the transmitting member 16 via another member. The adhesive 18 can be properly selected in consideration of the bonding strength or durability, etc. For example, a sol-gel silica glass, a sol-gel titania glass, a dimethyl silicone, etc., can be used. Further, a thickness of a layer made of the adhesive 18 is, for example, 20 μm or less, more preferably 3 μm or less.

In this way, since it is possible to form a thin layer as the adhesive 18, heat is easily transferred from the optical wavelength conversion member 14 to the transmitting member 16. Further, by employing the dimethyl silicone as the adhesive 18, the deterioration of the adhesive can be reduced even when the light emitted from the semiconductor light emitting element 12 is ultraviolet light or short-wavelength visible hot. As such, the dimethyl silicone is a material having a good balance from the view point of the deterioration due to the ultraviolet light or the like, heat resistance and transmittance, etc. Meanwhile, the optical wavelength conversion member 14 and the transmitting member 16 may be directly bonded to each other without using the adhesive. As a bonding method, for example, room-temperature bonding, plasma bonding and anodic bonding, etc., can be exemplified. Further, the semiconductor light emitting element 12 and the transmitting member 16 may be bonded to each other by using the adhesive 18 or a heat-transfer member, etc. In this way, the heat generated from the semiconductor light emitting element 12 can be also dissipated to the outside via the transmitting member 16.

### (Mounting Substrate)

As the mounting substrate 20 for mounting the semiconductor light emitting element 12, a metal substrate (aluminum substrate, copper substrate, etc.), a ceramic substrate (alumina substrate, aluminum nitride substrate, etc.), a resin substrate (glass epoxy substrate, etc. a lead frame, a lead frame integrated with a resin frame, a flexible substrate (FPC), etc., can be exemplified. The substrate is selected in consideration of the thermal conductivity, electrical insulation and cost, etc.

### Second Embodiment

FIG. 2 is a view showing a schematic configuration of a light emitting, module 30 according to a second embodiment. Here, the same components as in the first embodiment are denoted by the same reference numerals and a description thereof is omitted, as appropriate. The light emitting module 30 includes a semiconductor light emitting element 32, the optical wavelength conversion member 14, the transmitting member 16, and the transparent adhesive 18. The optical wavelength conversion member 14 converts the wavelength of element light emitted from the semiconductor light emitting element 32 and emits converted light having a color different from the element light. The transmitting member 16 is disposed between the semiconductor light emitting element 32 and the optical wavelength conversion member 14 and allows the element light to be transmitted therethrough. The adhesive 18 is provided for bonding the optical wavelength conversion member 14 and the transmitting member 16 to each other.

An outer edge of the transmitting member 16 is held in a housing 34. The housing also serves as a heat sink. The housing 34 is made of a material that is lightweight and has good thermal conductivity. As the material of the housing 34, for example, a metal material such as aluminum, magnesium, titanium, iron, copper, stainless steel, silver or nickel, or a plastic material with high thermal conductivity, in which fillers with good thermal conductivity are mixed is preferred.

As the semiconductor light emitting element 32 according to the second embodiment, a GaN-based LD element for emitting ultraviolet ray or short-wavelength visible light (near-ultraviolet light to blue light) is used. Further, it is preferable that the light emitted from the semiconductor light emitting element 32 is ultraviolet ray or short-wavelength visible light, which has a peak wavelength in a wavelength region of 365 to 470 nm (preferably, 380 to 430 nm). Further, the transmitting member 16 is disposed at a place that is spaced apart from a light emitting portion 32a of the semiconductor light emitting element 32.

In this way, air (n=1) with small refractive index (n) is present on the front of the light emitting portion 32a of the semiconductor light emitting element 32 that is an LD element. That is, the refractive index difference between the air and GaN-based material (n=2.3 to 2.5) constituting an LD element becomes larger, so that the oscillation of the laser diode is effectively performed.

Further, in the optical wavelength conversion member 14 according to the second embodiment, the reflective film 24 is provided on the side 14b of the surroundings of the light emitting surface 14a. The reflective film 24 reflects the converted light, which is generated in the optical wavelength conversion member 14 and directed to the side 14b, toward the front (upward in FIG. 2) of the light emitting module 30. In this way it is possible to improve the brightness of the light emitting module 30.

As such, in the case of using the LD element as the semiconductor light emitting element 32, the irradiation region of the element light can be narrowed, as compared to the case of using the LED element. Accordingly, it is possible to improve the brightness. On the other hand, since the element light is concentrated on the narrow region of the optical wavelength conversion member 14, the heat generated in the irradiation region is increased. Accordingly, the light emitting module 30 is configured so that the heat in the optical wavelength conversion member 14 is transferred to the housing 34 via the transmitting member 16. As a result, the heat dissipation is improved.

### Third Embodiment

FIG. 3 is a view showing a schematic configuration of a light emitting module 40 according to a third embodiment. The light emitting module according to the third embodiment is characterized in that a short pass filter is provided in the light emitting module according to the second embodiment. Accordingly the same components as in the second embodiment are denoted by the same reference numerals and a description thereof is omitted, as appropriate.

A short pass filter 42 is formed on the side of the transmitting member 16 of the light emitting module 40 facing the optical wavelength conversion member 14. That is, the optical wavelength conversion member 14 is bonded to the transmitting member 16 having the short pass filter 42 by the adhesive 18. Typically, the converted light in the optical wavelength conversion member 14 has a wavelength longer than the element light of the semiconductor light emitting element 32. Further, since the light converted by the phosphor is Lambertian light, a portion of the light is directed toward the semiconductor light emitting element 32. The element light of the semiconductor light emitting element 32 is allowed to be transmitted through the short pass filter 42 and the converted light in the optical wavelength conversion member 14 is not transmitted but reflected by the short pass filter 42. By using the short pass filter 42 thus configured, it is possible to realize a light emitting module with higher brightness.

Meanwhile, the arrangement position of the short pass filter 42 is not limited to the configuration of FIG. 3. The short pass filter 42 may be formed on the incident side 14c of the optical wavelength conversion member 14. In this case, the transmitting member 16 is bonded to the optical wavelength conversion member 14 having the short pass filter 42 by the adhesive 18.

Hereinabove, the present invention has been described with reference to each illustrative embodiment described above. However, the present invention is not limited to these illustrative embodiments. A suitable combination or substitution for the configuration of each illustrative embodiment is also intended to be included in the present invention. Further, based on the knowledge of those skilled in the art, the combination or the order of processing in each illustrative embodiment can be appropriately changed or a modification such as various design changes can be added to each illustrative embodiment. An illustrative embodiment to which such modification is added can be also included to the scope of the present invention.

What is claimed is:

1. A light emitting module comprising:
a semiconductor light emitting element;
an optical wavelength conversion member configured to convert the wavelength of element light emitted from the semiconductor light emitting element and to emit converted light having a color different from the element light;
a transmitting member disposed between the semiconductor light emitting element and the optical wavelength conversion member and configured to allow the element light to be transmitted therethrough, the transmitting member being made of a thermal conductive material that transfers the heat generated from the optical wavelength conversion member to the outside; and
a transparent adhesive bonding the optical wavelength conversion member and the transmitting member to each other, the adhesive having, a thickness of 20 μm or less.

2. The light emitting module according to claim 1, wherein the transmitting member has light transmittance of 40% or more and thermal conductivity of 10 W/(m·K) or more.

3. The light emitting module according to claim 1, wherein the semiconductor light emitting element emits ultraviolet light or short-wavelength visible light.

4. The light emitting module according to claim 1, wherein the semiconductor light emitting element is a laser diode, and
the transmitting member is disposed at a place that is spaced apart from a light emitting portion of the semiconductor light emitting element.

5. The light emitting module according to claim 1, wherein the transmitting member is made of a material having thermal conductivity higher than that of the optical wavelength conversion member.
